(19) United States
(12) Patent Application Publication
(10) Pub. No.: US 2025/0201619 A1
(43) Pub. Date: Jun. 19, 2025

(54) SHEET FOR WORKPIECE PROCESSING AND MANUFACTURING METHOD OF PROCESSED WORKPIECE

(71) Applicant: LINTEC CORPORATION, Tokyo (JP)

(72) Inventor: Akio FUKUMOTO, Tokyo (JP)

(73) Assignee: LINTEC CORPORATION, Tokyo (JP)

(21) Appl. No.: 18/842,614

(22) PCT Filed: Dec. 20, 2022
(86) PCT No.: PCT/JP2022/046791

§ 371 Date: Aug. 29, 2024

(30) Foreign Application Priority Data
Mar. 9, 2022 (JP) 2022-036269

(51) Int. Cl. H01L 21/683; C09J 7/38; C09J 11/06; C09J 133/08; H01L 21/324; H10D 89/00

(52) U.S. Cl. CPC H01L 21/6836; C09J 7/38; C09J 11/06; C09J 133/08; H01L 21/324; H10D 89/013; C09J 2301/302; C09J 2301/408; C09J 2301/50; C09J 2433/00; H01L 2221/68318; H01L 2221/68327; H01L 2221/68381

(57) ABSTRACT

Provided is a sheet for workpiece processing that includes a base material and a pressure sensitive adhesive layer laminated on one side of the base material. The pressure sensitive adhesive layer is composed of an active energy ray-curable pressure sensitive adhesive that contains a hindered amine-based stabilizer. Such a sheet for workpiece processing enables easy separation of workpieces even when a heating treatment is performed.

### TECHNICAL FIELD

The present invention relates to a sheet for workpiece processing that can be suitably used for processing a workpiece such as a semiconductor wafer, and a method of manufacturing processed workpieces using the sheet for workpiece processing. In particular, the present invention relates to a sheet for workpiece processing that can be suitably used in a workpiece processing method that includes a step of heating the sheet for workpiece processing in a state in which a workpiece or workpieces before or after processing are laminated, and relates also to a method of manufacturing processed workpieces using the sheet for workpiece processing.

### BACKGROUND ART

A method of manufacturing semiconductor devices generally includes a dicing step of singulating (dicing) a semiconductor wafer as a workpiece on a sheet for workpiece processing to obtain a plurality of semiconductor chips and a pickup step of picking up the obtained individual semiconductor chips from the sheet for workpiece processing. The above-described sheet for workpiece processing usually includes a base material and a pressure sensitive adhesive layer provided on one side of the base material, and the workpiece is laminated on the surface of the pressure sensitive adhesive layer opposite to the base material (this surface may be referred to as a “pressure sensitive adhesive surface,” hereinafter).

In recent years, it has become increasingly common for a workpiece before processing or workpieces after processing to be subjected to heating treatment in a state in which the workpiece or workpieces are laminated on a sheet for workpiece processing. For example, a workpiece on a sheet for workpiece processing may be subjected to a treatment such as vapor deposition, sputtering, or baking for dehumidification, or a heating test may be conducted to confirm the reliability under a high-temperature environment. In such a treatment that involves heating, problems may occur in that the sheet for workpiece processing is deformed due to the heating and the sheet for workpiece processing is fused and attached to some equipment or the like. Therefore, it is also being considered to provide a predetermined heat resistance to a sheet for workpiece processing that is subjected to a step that involves heating.

As an example of a heat-resistant pressure sensitive adhesive sheet, Patent Document 1 discloses a sheet including a pressure sensitive adhesive layer (adhesive resin layer) whose gel fraction before and after heating satisfies a predetermined condition. Patent Document 2 discloses a sheet including a pressure sensitive adhesive layer having a specific range of rigidity (product of nanoindenter elastic modulus and thickness at 25° C.).

### PRIOR ART DOCUMENTS

### Patent Documents

[Patent Document 1] JP6546378B

[Patent Document 2] JP6887766B

### SUMMARY OF THE INVENTION

### Problems to be Solved by the Invention

Meanwhile, when the above-described heating treatment is performed on a sheet for workpiece processing, there is a problem in that the adhesive strength to the workpieces increases, making it difficult to separate the sheet for workpiece processing from the workpieces.

In a sheet for workpiece processing, it is generally performed to facilitate the separation of the workpieces through configuring the pressure sensitive adhesive layer of an active energy ray-curable pressure sensitive adhesive and curing the pressure sensitive adhesive layer by active energy ray irradiation to reduce the adhesive strength to the workpieces.

According to the sheet for workpiece processing using such an active energy ray-curable pressure sensitive adhesive, the adhesive strength to the workpieces can be reduced to some extent even when the above-described heating treatment is carried out. With conventional sheets for workpiece processing, however, even when an active energy ray-curable pressure sensitive adhesives is used, the adhesive strength cannot be reduced sufficiently to enable easy separation of the workpieces after heating treatment.

The present invention has been made in view of such actual circumstances, and an object of the present invention is to provide a sheet for workpiece processing that enables easily separation of workpieces even when heating treatment is carried out.

### Means for Solving the Problems

To achieve the above object, first, the present invention provides a sheet for workpiece processing, comprising: a base material; and a pressure sensitive adhesive layer laminated on one side of the base material, the pressure sensitive adhesive layer being composed of an active energy ray-curable pressure sensitive adhesive that contains a hindered amine-based stabilizer (Invention 1).

In the sheet for workpiece processing according to the above invention (Invention 1), the pressure sensitive adhesive layer is composed of an active energy ray-curable pressure sensitive adhesive that contains a hindered amine-based stabilizer, so that even after the heating treatment, the pressure sensitive adhesive layer can be well cured by active energy ray irradiation, and the adhesive strength can be sufficiently reduced accordingly. Therefore, with the above sheet for workpiece processing, the workpiece can be easily separated even after the heating treatment.

In the above invention (Invention 1), the hindered amine-based stabilizer may be preferably an N-alkyl type hindered amine-based stabilizer (Invention 2).

In the above invention or inventions (Inventions 1 and 2), the active energy ray-curable pressure sensitive adhesive may be preferably formed from a pressure sensitive adhesive composition that contains an acrylic-based polymer having a side chain to which an active energy ray-curable group is introduced and the hindered amine-based stabilizer (Invention 3).

In the above invention or inventions (Inventions 1 to 3), the sheet for workpiece processing may be preferably used in a workpiece processing method comprising a step of heating the sheet for workpiece processing in a state in which a workpiece or workpieces before or after processing are laminated on a side of the pressure sensitive adhesive layer opposite to the base material (Invention 4).

Second, the present invention provides a method of manufacturing processed workpieces, comprising: a bonding step of bonding a workpiece to a surface of the pressure sensitive adhesive layer opposite to the base material in the sheet for workpiece processing (Invention or inventions 1 to 4); a heating step of subjecting the workpiece to a treatment that involves heating in a state in which the workpiece is laminated on the sheet for workpiece processing; and a dicing step of dicing, on the sheet for workpiece processing, the workpiece subjected to the treatment that involves heating, thereby obtaining processed workpieces that are singulated from the workpiece (Invention 5).

### Advantageous Effect of the Invention

The sheet for workpiece processing according to the present invention allows the workpieces to be easily separated even when heating treatment is carried out.

### EMBODIMENTS FOR CARRYING OUT THE INVENTION

Hereinafter, one or more embodiments of the present invention will be described.

The sheet for workpiece processing according to the present embodiment includes a base material and a pressure sensitive adhesive layer laminated on one side of the base material. In addition, the pressure sensitive adhesive layer is composed of an active energy ray-curable pressure sensitive adhesive that contains a hindered amine-based stabilizer.

In the sheet for workpiece processing according to the present embodiment, the pressure sensitive adhesive layer is composed of an active energy ray-curable pressure sensitive adhesive, so that the pressure sensitive adhesive layer can be cured by active energy ray irradiation thereby to reduce the adhesive strength to the workpiece. Therefore, when it is desired to separate the sheet for workpiece processing according to the present embodiment from the workpiece, it is possible to prevent the workpiece from being destroyed and suppress attachment of a part of the pressure sensitive adhesive, which constitute the pressure sensitive adhesive layer, to the workpiece (adhesive residue), thus facilitating the separation.

Furthermore, in the sheet for workpiece processing according to the present embodiment, the above active energy ray-curable pressure sensitive adhesive contains a hindered amine-based stabilizer, so that even when the sheet for workpiece processing is heated (in particular, even when the sheet for workpiece processing is heated in a state in which a workpiece or workpieces are laminated thereon), subsequent irradiation with active energy rays allows the sheet to be easily separated from the workpiece or workpieces as described above.

Conventionally, it has been known that when a sheet for workpiece processing is subjected to heating treatment in a state in which a workpiece or workpieces are laminated thereon, the adhesive strength to the workpiece or workpieces increases and it becomes difficult to separate the workpiece or workpieces. Furthermore, the inventor and his colleagues have confirmed that even when the pressure sensitive adhesive layer of the sheet for workpiece processing is composed of an active energy ray-curable pressure sensitive adhesive, if it undergoes heating treatment, not only does the adhesive strength simply increase, but also the curing of the pressure sensitive adhesive layer due to active energy ray irradiation (and the resulting decrease in adhesive strength) itself is less likely to occur.

Fortunately, however, in the sheet for workpiece processing according to the present embodiment, even after the heating treatment, it is possible to satisfactorily perform the curing of the pressure sensitive adhesive layer due to active energy ray irradiation (and the resulting decrease in adhesive strength). The reasons for this are expected to be as follows. However, this is not limited to the following reasons, and does not deny the possibility that other reasons may exist.

It is considered that when an active energy ray-curable pressure sensitive adhesive is heated, thermal decomposition various elimination (including depolymerization and reactions) and oxidation (including peroxide formation) occur in the polymers and additives that constitute the pressure sensitive adhesive, and active radicals are generated. The active radicals appear to cause further decomposition or oxidation of the polymers, denaturation or deactivation of sites that play an important role in active energy ray curing (in particular, carbon-carbon double bonds), or thermal polymerization. In the sheet for workpiece processing according to the present embodiment, however, it is believed that the hindered amine-based stabilizer, the resulting radicals generated in the system, etc. trap and deactivate the active radicals and growing terminals generated under high-temperature environment as described above, thereby preventing the above-described denaturation of the active energy ray-curable pressure sensitive adhesive.

In particular, after the hindered amine-based stabilizer traps radicals (bonds with radicals), a reaction in which the radical moiety is separated again proceeds, and it is regenerated as a hindered amine-based stabilizer. The hindered amine-based stabilizer can therefore continuously exhibit its effect as a stabilizer. Such a regenerating action does not occur with hindered phenol-based compounds that have been used conventionally.

According to the above-described action, in the sheet for workpiece processing according to the present embodiment, even when the heating treatment is performed after the pressure sensitive adhesive layer is cured by irradiation with active energy rays, excessive increase in the adhesive strength is suppressed, and the workpiece or workpieces can be separated satisfactorily.

### 1. Base Material

The base material in the present embodiment is not particularly limited, provided that it exhibits the desired function when the sheet for workpiece processing is used. In particular, the base material in the present embodiment is preferably composed of resin, and examples of the resin include: polyester-based resins such as polyethylene terephthalate, polybutylene terephthalate, and polyethylene naphthalate; polyolefin-based resins such as polyethylene, polypropylene, polybutene, polybutadiene, polymethylpentene, ethylene-norbornene copolymer, and norbornene resin; ethylene-based copolymer resins such as ethylene-vinyl acetate copolymer, ethylene-(meth)acrylic acid copolymer, ethylene-methyl (meth)acrylate copolymer, and other ethylene-(meth)acrylic ester copolymers; polyvinyl chloride-based resins such as polyvinyl chloride and vinyl chloride copolymers; (meth)acrylic ester copolymers; polyurethane; polyimide; polystyrene; polycarbonate; and fluorine resin. The resin constituting the base material may be a crosslinked resin of the above-described resin or a modified version of the above-described resin, such as an ionomer. As used in the present specification, the term “(meth)acrylic acid” refers to both the acrylic acid and the methacrylic acid. The same applies to other similar terms. As used in the present specification, the term “polymer” encompasses the concept of a “copolymer.”

The base material in the present embodiment may be a single layer film composed of the above-described resin or may also be a laminated film formed by laminating a plurality of such films. In this laminated film, the materials constituting respective layers may be the same or different.

Additionally or alternatively, the base material in the present embodiment may include one or more oligomer sealing layers on one surface or both surfaces of the film composed of the above-described resin. The oligomer sealing layer refers to a layer for suppressing the release of low-molecular weight components (oligomers) contained inside the above-described resin to the outside of the base material when the base material is heated. Such oligomers include residues and modified products such as those of the raw materials and solvents used in the production of the above resin, decomposition products of the resin itself, residues or the like of the solvents used in the production of the base material, etc., and their reaction products. These usually volatilize or diffuse when heated and are readily released from the base material to the outside, but by providing the oligomer sealing layer, the above oligomers are prevented from migrating/adhering to the pressure sensitive adhesive layer, workpiece, equipment, etc., and it is possible to prevent adverse effects caused by the oligomers.

The above oligomer sealing layer can be, for example, a cured film obtained by curing a composition for oligomer sealing layer containing an epoxy compound, a polyester compound, and a polyfunctional amino compound. The composition for oligomer sealing layer may further contain an acidic catalyst from the viewpoint of promoting the above curing reaction.

Additionally or alternatively, the base material may contain various additives such as flame retardants, plasticizers, antistatics, glidants, antioxidants, colorants, infrared absorbers, ultraviolet absorbers, and ion scavengers. The content of these additives is not particularly limited, but may be preferably within a range in which the base material can exhibit the desired functions.

The surface of the base material on which the pressure sensitive adhesive layer is laminated may be subjected to surface treatment such as primer treatment, corona treatment, or plasma treatment in order to increase the interfacial adhesion with the pressure sensitive adhesive layer.

The thickness of the base material may be appropriately set depending on the method in which the sheet for workpiece processing is used. For example, the thickness of the base material may be preferably 200 μm or less and particularly preferably 150 μm or less. From another aspect, the thickness of the base material may be preferably 10 μm or more and particularly preferably 25 μm or more.

### 2. Pressure Sensitive Adhesive Layer

As described previously, the pressure sensitive adhesive layer in the present embodiment is composed of an active energy ray-curable pressure sensitive adhesive that contains a hindered amine-based stabilizer.

Examples of the above pressure sensitive include, but are not limited to, acrylic-based adhesives, rubber-based adhesives, silicone-based adhesives, urethane-based adhesives, polyester-based adhesives, and polyvinyl ether-based adhesives. However, it is preferred to use an acrylic-based adhesive from the viewpoint that an active energy ray-curable pressure sensitive adhesive is readily formed and desired adhesive strength can be readily exhibited.

The above active energy ray-curable pressure sensitive adhesive may contain as the main component a polymer having active energy ray-curable properties and may also contain as the main component a mixture of an active energy ray-noncurable polymer (polymer having no active energy ray-curable properties) and a monomer and/or oligomer having at least one or more active energy ray-curable groups. The active energy ray-curable pressure sensitive adhesive may also be a mixture of a polymer having active energy ray-curable properties and a monomer and/or oligomer having at least one or more active energy ray-curable groups. Among these, the active energy ray-curable pressure sensitive adhesive in the present embodiment may preferably contain as the main component a polymer having active energy ray-curable properties (in particular, an acrylic-based polymer having active energy ray-curable properties) from the viewpoints that even after the heating treatment, the adverse effects of an excessive increase in the adhesive strength can be suppressed and the use of a trigger to reduce the adhesive strength makes it easier to separate the workpiece or workpieces.

The above acrylic-based polymer having active energy ray curable properties may be preferably an acrylic-based polymer in which a functional group having energy ray-curable properties (an active energy group) ray-curable is introduced into a side chain (this acrylic-based polymer may be referred to as an “active energy ray-curable polymer (A),” hereinafter). In this case, the active energy ray-curable pressure sensitive adhesive in the present embodiment may be preferably formed from a pressure sensitive adhesive composition that contains an acrylic-based polymer in which an active energy ray-curable group is introduced into a side chain (active energy ray-curable polymer (A)) and a hindered amine-based stabilizer.

### (1) Active Energy Ray-Curable Polymer (A)

The above active energy ray-curable polymer (A) may be preferably obtained by reacting a (meth)acrylic ester polymer (a1) having a functional group-containing monomer unit with an unsaturated group-containing compound (a2) having a functional group that can be bonded to the functional group of the (meth)acrylic ester copolymer (a1).

The above-described functional group-containing monomer may be preferably a monomer having a polymerizable double bond and a functional group such as a hydroxy group, a carboxyl group, an amino group, an amide group, a benzyl group, or a glycidyl group in the molecule. It is preferred to use a monomer containing a hydroxy group, among the above, as the functional group (hydroxy group-containing monomer).

Examples of the hydroxy group-containing monomer include 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, and 4-hydroxybutyl (meth)acrylate, among which at least one of 2-hydroxyethyl acrylate and 4-hydroxybutyl acrylate may be preferably used. These may each be used alone or two or more types may also be used in combination.

Examples of the above carboxyl group-containing monomer include ethylenically-unsaturated carboxylic acids such as acrylic acid, methacrylic acid, crotonic acid, maleic acid, itaconic acid, and citraconic acid. These may each be used alone or two or more types may also be used in combination.

Examples of the above amino group-containing monomer or amide group-containing monomer include aminoethyl (meth)acrylate and n-butylaminoethyl (meth)acrylate. These may each be used alone or two or more types may also be used in combination.

The (meth)acrylic ester polymer (a1) may preferably contain 5 mass % or more and particularly preferably 10 mass % or more of the structural unit derived from the above functional group-containing monomer. From another aspect, the (meth)acrylic ester polymer (a1) may preferably contain 40 mass % or less and particularly preferably 35 mass % or less of the structural unit derived from the above functional group-containing monomer. When the (meth)acrylic ester polymer (a1) contains the functional group-containing monomer in the above range, the desired active energy ray-curable polymer (A) can be readily formed.

From the viewpoint of facilitating the formation of a pressure sensitive adhesive having desired performance, the (meth)acrylic ester polymer (a1) may preferably contain (meth)acrylic alkyl ester as a monomer unit that constitutes the polymer. The (meth)acrylic alkyl ester may be preferably one whose carbon number of alkyl group is 1 to 18 and particularly preferably one whose carbon number of alkyl group is 1 to 8.

Specific examples of the above (meth)acrylic alkyl ester include methyl (meth)acrylate, ethyl (meth)acrylate, propyl (meth)acrylate, n-butyl (meth)acrylate, n-pentyl (meth)acrylate, n-hexyl (meth)acrylate, 2-ethylhexyl (meth)acrylate, isooctyl (meth)acrylate, n-decyl (meth)acrylate, lauryl (meth)acrylate, myristyl (meth)acrylate, palmityl (meth)acrylate, and stearyl (meth)acrylate. These may each be used alone or two or more types may also be used in combination. It may be preferred to use 2-ethylhexyl (meth)acrylate and particularly preferred to use 2-ethylhexyl acrylate among the above-described (meth)acrylic acid alkyl esters.

The (meth)acrylic ester polymer (a1) may preferably contain 20 mass % or more and particularly preferably 40 mass % or more of the structural unit derived from the above (meth)acrylic alkyl ester. From another aspect, the (meth)acrylic ester polymer (a1) may preferably contain 95 mass % or less and particularly preferably 85 mass % or less of the structural unit derived from the above (meth)acrylic alkyl ester. When the (meth)acrylic ester polymer (a1) contains the (meth)acrylic alkyl ester in the above range, the sheet for workpiece processing can readily exhibit desired adhesive strength.

It is also preferred that the (meth)acrylic ester polymer (a1) should contain a nitrogen atom-containing monomer as a monomer unit that constitutes the (meth)acrylic ester polymer (a1). This allows the workpiece to be held better on the sheet for workpiece processing when processing the workpiece, and when the sheet for workpiece processing is heated, an excessive increase in the adhesive strength to the workpiece or workpieces can be readily suppressed. Examples of the nitrogen atom-containing monomer include monomers having an amino group, monomers having an amide group, and monomers having a nitrogen-containing heterocycle, among which monomers having a nitrogen-containing heterocycle may be preferred.

Examples of monomers having a nitrogen-containing heterocycle include N-(meth)acryloylmorpholine, N-vinyl-2-pyrrolidone, N-(meth)acryloylpyrrolidone, N-(meth)acryloylpiperidine, N-(meth)acryloylpyrrolidine, N-(meth)acryloylaziridine, aziridinylethyl(meth)acrylate, 2-vinylpyridine, 4-vinylpyridine, 2-vinylpyrazine, 1-vinylimidazole, N-vinylcarbazole, and N-vinylphthalimide, among which N-(meth)acryloylmorpholine may be preferred, and N-acryloylmorpholine may be particularly preferred.

The (meth)acrylic ester polymer (a1) may preferably contain 3 mass % or more, particularly preferably 5 mass % or more, and further preferably 8 mass % or more of the structural unit derived from the above nitrogen atom-containing monomer. From another aspect, the (meth)acrylic ester polymer (a1) may preferably contain 12 mass % or less, particularly preferably 11 mass % or less, and further preferably 10 mass % or less of the structural unit derived from the above nitrogen atom-containing monomer. By containing the nitrogen atom-containing monomer in the (meth)acrylic ester polymer (a1) in the above range, it is possible to better hold the workpiece on the sheet for workpiece processing when processing the workpiece, and when the sheet for workpiece processing is heated, an excessive increase in the adhesive strength to the workpiece or workpieces can be readily suppressed.

The (meth)acrylic ester polymer (a1) may contain one or more other monomers in addition to the above-described functional group-containing monomer, (meth)acrylic acid alkyl ester, and nitrogen atom-containing monomer as monomer units that constitute the (meth)acrylic ester polymer (a1).

Examples of the above other monomers include alkoxyalkyl group-containing (meth)acrylic esters such as methoxymethyl (meth)acrylate, methoxyethyl (meth)acrylate, ethoxymethyl (meth)acrylate, and ethoxyethyl (meth)acrylate; (meth)acrylic esters having an aliphatic ring, such as cyclohexyl (meth)acrylate; (meth)acrylic esters having an aromatic ring, such as phenyl (meth)acrylate; non-crosslinkable acrylamides such as (meth)acrylamide and N, N-dimethyl (meth)acrylamide; (meth)acrylic esters having a non-crosslinkable tertiary amino group, such as N, N-dimethylaminoethyl (meth)acrylate and N, N-dimethylaminopropyl (meth)acrylate; vinyl acetate; and styrene.

The polymerization form of the (meth)acrylic ester polymer (a1) may be a random copolymer or may also be a block copolymer. The polymerization method is not particularly limited, and polymerization can be performed by a general polymerization method, for example, a solution polymerization method.

The active energy ray-curable polymer (A) can be obtained by reacting the above (meth)acrylic ester polymer (a1) having a functional group-containing monomer unit with the unsaturated group-containing compound (a2) having a functional group that can be bonded to the functional group of the (meth)acrylic ester polymer (a1).

The functional group of the unsaturated group-containing compound (a2) can be appropriately selected in accordance with the functional group type of the functional group-containing monomer unit of the (meth)acrylic ester polymer (a1). For example, when the functional group of the (meth)acrylic ester polymer (a1) is a hydroxy group, an amino group, or a carboxyl group, the functional group of the unsaturated group-containing compound (a2) may be preferably an isocyanate group, an epoxy group, or an aziridinyl group. When the functional group of the (meth)acrylic ester polymer (a1) is a glycidyl group, the functional group of the unsaturated group-containing compound (a2) may be preferably an amino group, a carboxyl group, or an aziridinyl group.

The above unsaturated group-containing compound (a2) may contain at least one, preferably 1 to 6, and further preferably 1 to 4 active energy ray-polymerizable carbon-carbon double bonds. Specific examples of such an unsaturated group-containing compound (a2) include 2-methacryloyloxyethyl isocyanate; 2-acryloyloxyethyl isocyanate; 2-(2-methacryloyloxyethyloxy)ethyl isocyanato; 1,1-(bisacryloyloxymethyl)ethyl isocyanate; meta-isopropenyl-α,α-dimethylbenzyl isocyanate; methacryloyl isocyanate; allyl isocyanate; 1,1-(bisacryloyloxymethyl)ethyl isocyanate; an acryloyl monoisocyanate compound obtained by reaction between a diisocyanate compound or polyisocyanate compound and hydroxyethyl (meth)acrylate; an acryloyl monoisocyanate compound obtained by reaction of a diisocyanate compound or polyisocyanate compound, a polyol compound, and hydroxyethyl (meth)acrylate; glycidyl (meth)acrylate; (meth)acrylic acid; 2-(1-aziridinyl)ethyl (meth)acrylate; 2-vinyl-2-oxazoline; and 2-isopropenyl-2-oxazoline.

The above unsaturated group-containing compound (a2) may be used preferably at 50 mol % or more, particularly preferably at 60 mol % or more, and further preferably at 70 mol % or more as the ratio with respect to the molar number of the functional group-containing monomer of the above (meth)acrylic ester polymer (a1). From another aspect, the above unsaturated group-containing compound (a2) may be used preferably at 95 mol % or less, particularly preferably at 93 mol % or less, and further preferably at 90 mol % or less as the ratio with respect to the molar number of the functional group-containing monomer of the above (meth)acrylic ester polymer (a1).

In the reaction between the (meth)acrylic ester polymer (a1) and the unsaturated group-containing compound (a2), the reaction temperature, pressure, solvent, time, presence or absence of catalyst, of and type catalyst can be appropriately selected in accordance with the combination of the functional group of the (meth)acrylic ester polymer (a1) and the functional group of the unsaturated group-containing compound (a2). This allows the reaction to proceed between the functional group existing in the (meth)acrylic ester polymer (a1) and the functional group in the unsaturated group-containing compound (a2), so that the unsaturated group is introduced into a side chain of the (meth)acrylic ester polymer (a1), and the active energy ray-curable polymer (A) can thus be obtained.

The weight-average molecular weight (Mw) of the active energy ray-curable polymer (A) thus obtained may be preferably 10,000 or more, particularly preferably 150,000 or more, and further preferably 200,000 or more. From another aspect, the weight-average molecular weight (Mw) may be preferably 1,500,000 or less and particularly preferably 1,000,000 or less.

### (2) Hindered Amine-Based Stabilizer

As used in the present specification, the term “hindered amine-based stabilizer” refers to a stabilizer having one or more amine skeletons in its molecule. The hindered amine-based stabilizer in the present embodiment is not particularly limited, provided that it has such a structure.

In general, there are an N-alkyl type hindered amine-based stabilizer, an NH type hindered amine-based stabilizer, etc. as hindered amine-based stabilizers. The N-alkyl type hindered amine-based stabilizer is a compound having one or more structures in the molecule in which alkyl groups are bonded to nitrogen of atoms the 2,2,6,6-tetramethylpiperidine skeleton. The NH type hindered amine-based stabilizer is a compound having one or more structures in the molecule in which hydrogen atoms are bonded to nitrogen atoms of the 2,2,6,6-tetramethylpiperidine skeleton. In the sheet for workpiece processing according to the present embodiment, satisfactory effects can be obtained even when any of these compounds is used, but it may be preferred to use the N-alkyl type hindered amine-based stabilizer from the viewpoint that the adhesive strength to the workpiece or workpieces can readily be well reduced after heating and after active energy ray irradiation.

Examples of the alkyl group in the above N-alkyl type hindered amine-based stabilizer include methyl group, ethyl group, n-propyl group, isopropyl group, n-butyl group, n-pentyl group, n-hexyl group, and n-octyl group, among which the methyl group may be preferred from the viewpoint of readily and satisfactorily reducing the adhesive strength to the workpiece or workpieces after heating and after active energy ray irradiation.

Specific examples hindered amine-based of the stabilizer include p,p′-dioctyldiphenylamine, phenyl-α-naphthylamine, poly (2,2,4-trimethyl-1,2-dihydroquinoline), 6-ethoxy-2,2,4-trimethyl-1,2-dihydroquinoline, N,N′-diphenyl-p-phenylenediamine, N,N′-di-β-naphthyl-p-phenylenediamine, N-phenyl-N′-isopropyl-p-phenylenediamine, N,N′-diallyl-p-phenylenediamine, 4,4′-(α,α-dimethylbenzyl)diphenylamine, p,p-toluenesulfonylaminodiphenylamine, N-phenyl-N′-(3-methacryloxy-2-hydroxypropyl)-p-phenylenediamine, N-(1-methylheptyl)-N′-phenyl-p-phenylenediamine, N,N′-di-sec-butyl-p-phenylenediamine, N-phenyl-N′-1,3-dimethylbutyl-p-phenylenediamine, alkylated diphenylamine, dimethyl-1-(2-hydroxyethyl)-4-hydroxy-2,2,6,6-tetramethylpiperidine succinate polycondensate, poly[[6-(1,1,3,3-tetramethylbutyl)amino-1,3,5-triazine-2,4-diyl][(2,2,6,6-tetramethyl-4-piperidyl)imino]hexamethylene[(2,2,6,6-tetramethyl-4-piperidyl)imino]], N,N′-bis(3-aminopropyl)ethylenediamine-2,4-bis[N-butyl-N-(1,2,2,6,6-pentamethyl-4-piperidyl)amino]-6-chloro-1,3,5-triazine condensate, bis(1-octyloxy-2,2,6,6-tetramethyl-4-piperidyl) sebacate, bis (2,2,6,6-tetramethyl-4-piperidyl) sebacate, 2-(3,5-di-tert-butyl-4-hydroxybenzyl)-2-n-butylmalonate bis (1,2,2,6,6-pentamethyl-4-piperidyl), bis (1,2,2,6,6-pentamethyl-4-piperidyl) sebacate, tetrakis (1,2,2,6,6-pentamethyl-4-piperidyl) 1,2,3,4-butanetetracarboxylate, tetrakis (2,2,6,6-tetramethyl-4-piperidyl) 1,2,3,4-butanetetracarboxylate, mixed ester of 1,2,3,4-butanetetracarboxylic acid and 1,2,2,6,6-pentamethyl-4-piperidinol and 1-tridecanol, mixed ester of 1,2,3,4-butanetetracarboxylic acid and 1,2,2,6,6-pentamethyl-4-piperidinol and 3,9-bis(2-hydroxy-1,1-dimethylethyl)-2,4,8,10-tetraoxaspiro[5.5]undecan, mixed ester of 1,2,3,4-butanetetracarboxylic acid and 2,2,6,6-tetramethyl-4-piperidinol and 3,9-bis(2-hydroxy-1,1-dimethylethyl)-2,4,8,10-tetraoxaspiro[5.5]undecane, and (2,2,6,6-tetramethylene-4-piperidyl)-2-propylenecarboxylate, (1,2,2,6,6-pentamethyl-4-piperidyl)-2-propylenecarboxylate.

It may be preferred to use, among the above specific examples, at least one of tetrakis (2,2,6,6-tetramethyl-4-piperidyl) 1,2,3,4-butanetetracarboxylate as an N-alkyl type hindered amine-based stabilizer, mixed ester of 1,2,3,4-butanetetracarboxylic acid and 1,2,2,6,6-pentamethyl-4-piperidinol and 3,9-bis(2-hydroxy-1,1-dimethylethyl)-2,4,8,10-tetraoxaspiro[5.5]undecan as an N-alkyl type hindered amine-based stabilizer, and tetrakis (1,2,2,6,6-pentamethyl-4-piperidyl)1,2,3,4-butanetetracarboxylate as an NH type hindered amine-based stabilizer.

The molar mass of the hindered amine-based stabilizer may be preferably 200 g/mol or more, particularly preferably 600 g/mol or more, and further preferably 1,000 g/mol or more. From another aspect, the molar mass may be preferably 10,000 g/mol or less, particularly preferably 5,000 g/mol or less, and further preferably 3,000 g/mol or less. When the molar mass of the hindered amine-based stabilizer is within these ranges, it becomes easier to reduce the adhesive strength to the workpiece or workpieces after heating and after active energy ray irradiation.

The content of the hindered amine-based stabilizer in the previously-described pressure sensitive adhesive composition may be preferably 0.1 mass parts or more, particularly preferably 0.5 mass parts or more, and further preferably 1.0 mass parts or more with respect to 100 mass parts of the acrylic-based polymer (active energy ray-curable polymer (A)) in which an active energy ray-curable group is introduced into a side chain. From another aspect, the content may be preferably 30 mass parts or less, particularly preferably 20 mass parts or less, and further preferably 15 mass parts or less. When the content of the hindered amine-based stabilizer is within these ranges, it becomes easier to reduce the adhesive strength to the workpiece or workpieces after heating and after active energy ray irradiation.

### (3) Crosslinker

It is also preferred that the previously-described pressure sensitive adhesive composition should contain a crosslinker. When the pressure sensitive adhesive composition contains a crosslinker, the active energy ray-curable polymer (A) can be crosslinked in the pressure sensitive adhesive layer to form a good three-dimensional network structure. This allows the obtained pressure sensitive adhesive to further improve its cohesive strength, and the occurrence of adhesive residue can be effectively suppressed in the workpiece or workpieces separated from the sheet for workpiece processing after irradiation with active energy rays. When the pressure sensitive adhesive composition contains a crosslinker, the active energy ray-curable polymer may preferably contain the above-described functional group-containing monomer as a monomer unit that constitutes the polymer, and may particularly preferably contain a functional group-containing monomer having a highly reactive functional group with the crosslinker used.

Examples of the above crosslinkers include an isocyanate-based crosslinker, an epoxy-based crosslinker, an amine-based crosslinker, a melamine-based crosslinker, an aziridine-based crosslinker, a hydrazine-based crosslinker, an aldehyde-based crosslinker, an oxazoline-based crosslinker, a metal alkoxide-based crosslinker, a metal chelate-based crosslinker, a metal salt-based crosslinker, and an ammonium salt-based crosslinker. The crosslinker can be selected depending on the functional group derived from the functional group-containing monomer possessed by the acrylic-based copolymer. One type of the crosslinker may be used alone or two or more types may also be used in combination.

The isocyanate-based crosslinker contains at least a polyisocyanate compound. Examples of the polyisocyanate compound include aromatic polyisocyanates such as tolylene diisocyanate, diphenylmethane diisocyanate, and xylylene diisocyanate, aliphatic polyisocyanates such as hexamethylene diisocyanate, alicyclic polyisocyanates such as isophorone diisocyanate and hydrogenated diphenylmethane diisocyanate, biuret bodies and isocyanurate bodies thereof, and adduct bodies that are reaction products with low molecular active hydrogen-containing compounds such as ethylene glycol, propylene glycol, neopentyl glycol, trimethylol propane, and castor oil. Among these, an isocyanurate body of hexamethylene diisocyanate, particularly an isocyanurate type trimer of 1,6-hexamethylene diisocyanate, may be preferred.

When the previously-described pressure sensitive adhesive composition contains a crosslinker, the content of the crosslinker in the pressure sensitive adhesive composition may be preferably 0.1 mass parts or more, particularly preferably 0.5 mass parts or more, and further preferably 3 mass parts or more with respect to 100 mass parts of the active energy ray-curable polymer (A). From another aspect, the content may be preferably 20 mass parts or less and particularly preferably 5 mass parts or less. When the content of the crosslinker is 0.1 mass parts or more, it is easier to improve the cohesive strength of the pressure sensitive adhesive layer after irradiation with active energy rays, and the adhesive residue can thereby be effectively suppressed. On the other hand, when the content of the crosslinker is 20 mass parts or less, the degree of crosslinking may be appropriate, and the pressure sensitive adhesive layer can readily exhibit the desired adhesive strength.

### (4) Photopolymerization Initiator

It is also preferred that the pressure sensitive adhesive composition in the present embodiment should contain a photopolymerization initiator. By containing the photopolymerization initiator in the pressure sensitive adhesive composition, it is possible to reduce the polymerization curing time and the amount of irradiation when curing the pressure sensitive adhesive layer by irradiation with active energy rays.

Examples of the photopolymerization initiator include benzophenone, acetophenone, benzoin, benzoin methyl ether, benzoin ethyl ether, benzoin isopropyl ether, benzoin isobutyl ether, benzoin benzoic acid, methyl benzoate, benzoin dimethyl ketal, 2,4-diethylthioxanthone, 1-hydroxycyclohexyl phenyl ketone, benzyl diphenyl sulfide, tetramethyl thiuram monosulfide, azobisisobutyronitrile, benzyl, dibenzyl, diacetyl, β-chloroanthraquinone, (2,4,6-trimethylbenzyldiphenyl) phosphine oxide, 2-benzothiazole-N,N-diethyl dithiocarbamate, oligo{2-hydroxy-2-methyl-1-[4-(1-propenyl)phenyl]propanone}, and 2,2-dimethoxy-1,2-diphenylethan-1-one. It may be preferred to use, among them, 1-hydroxycyclohexyl phenyl ketone. The above-described photopolymerization initiators may each be used alone or two or more types may also be used in combination.

When the previously-described pressure sensitive adhesive composition contains a photopolymerization initiator, the content of the photopolymerization initiator in the pressure sensitive adhesive composition may be preferably 0.1 mass parts or more and particularly preferably 1 mass part or more with respect to 100 mass parts of the active energy ray-curable polymer (A). From another aspect, the content may be preferably 10 mass parts or less and particularly preferably 5 mass parts or less. When the content of the photopolymerization initiator is within the above range, the pressure sensitive adhesive layer can be efficiently cured by irradiation with active energy rays, and the adhesive strength of the sheet for workpiece processing to an adherend can thereby be satisfactorily reduced.

### (5) Other Components

The previously-described pressure sensitive adhesive composition may contain desired additives, such as silane coupling agents, antistatics, tackifiers, antioxidants, softening agents, fillers, and refractive index modifiers, provided that the previously-described effects of the sheet for workpiece processing according to the present embodiment are not impaired.

### (6) Method of Preparing Pressure Sensitive Adhesive Composition

The pressure sensitive adhesive composition in the present embodiment can be manufactured through producing the active energy ray-curable polymer (A) and mixing the obtained active energy ray-curable polymer (A) with a hindered amine-based stabilizer and if desired further with a crosslinker, a photopolymerization initiator, and desired additives. At this time, a diluting solvent may be added if desired to obtain a coating liquid of the pressure sensitive adhesive composition.

Examples of the diluting solvent for use include aliphatic hydrocarbons such as hexane, heptane and cyclohexane, aromatic hydrocarbons such toluene and xylene, halogenated hydrocarbons such as methylene chloride and ethylene chloride, alcohols such as methanol, ethanol, propanol, butanol and 1-methoxy-2-propanol, ketones such as acetone, methyl ethyl ketone, 2-pentanone, isophorone and cyclohexanone, esters such as ethyl acetate and butyl acetate, and cellosolve-based solvents such as ethyl cellosolve.

The concentration/viscosity of the coating liquid thus prepared is not particularly limited and can be appropriately selected depending on the situation, provided that the concentration/viscosity is within a range in which the coating is possible. For example, the pressure sensitive adhesive composition may be diluted to a concentration of 10 mass % or more and 60 mass % or less. When obtaining the coating liquid, the addition of a diluting solvent or the like is not a necessary condition, and the diluting solvent may not be added if the pressure sensitive adhesive composition has a viscosity or the like that enables the coating. In this case, the pressure sensitive adhesive composition may be a coating liquid in which the polymerization solvent itself for the (meth)acrylic ester polymer (a1) is used as a diluting solvent.

### (7) Thickness of Pressure Sensitive Adhesive Layer

The thickness of the pressure sensitive adhesive layer in the present embodiment may be preferably 1 μm or more, particularly preferably 3 μm or more, and further preferably 5 μm or more. When the thickness of the pressure sensitive adhesive layer is 1 μm or more, the sheet for workpiece processing can readily exhibit good adhesive strength, and chip flying can be readily suppressed. From another aspect, the thickness may be preferably 50 μm or less, particularly preferably 30 μm or less, and further preferably 20 μm or less. When the thickness of the pressure sensitive adhesive layer is 50 μm or less, the workpiece or workpieces can be easily separated.

### 3. Other Configurations

In the sheet for workpiece processing according to the present embodiment, for the purpose of protecting the surface of the pressure sensitive adhesive layer opposite to the base material (pressure sensitive surface) until the surface is attached to a workpiece, a release sheet may be laminated on the surface.

The configuration of the above release sheet may be freely determined. Examples of the release sheet include those in which release treatment is performed for a plastic film, such as using a release agent. Specific examples of the plastic film include films of polyesters such as polyethylene terephthalate, polybutylene terephthalate, and polyethylene naphthalate and films of polyolefins such as polypropylene and polyethylene. Examples of the above release agent for use include silicone-based, fluorine-based, long-chain alkyl-based, and rubber-based release agents, among which the silicone-based release agent may be preferred because stable performance can be obtained at low cost.

The thickness of the above release sheet is not particularly limited, and may be, for example, 16 μm or more and 250 μm or less.

In the sheet for workpiece processing according to the present embodiment, an adhesive layer may be laminated on the surface of the pressure sensitive adhesive layer opposite to the base material. In this case, the sheet for workpiece processing according to the present embodiment can be used as a dicing/die bonding sheet. In this sheet, a workpiece is attached to the surface of the adhesive layer opposite to the pressure sensitive adhesive layer, and the adhesive layer can be diced together with the workpiece thereby to obtain chips on which singulated adhesive layers are laminated. The chips can be easily fixed by means of the singulated adhesive layers to an object on which the chips are to be mounted. Preferred materials used to constitute the above-described adhesive layer include those containing a thermoplastic resin and a low-molecular weight thermosetting adhesive component and those containing a B-stage (semi-cured) thermosetting adhesive component.

Furthermore, in the sheet for workpiece processing according to the present embodiment, a protective film forming layer may be laminated on the pressure sensitive adhesive surface of the pressure sensitive adhesive layer. In this case, the sheet for workpiece processing according to the present embodiment can be used as a sheet for protective film forming and dicing. In such a sheet, a workpiece is attached to the surface of the protective film forming layer opposite to the pressure sensitive adhesive layer, and the protective film forming layer can be diced together with the workpiece thereby to obtain chips on which singulated protective film forming layers are laminated. It may be preferred to use a workpiece having circuits formed on one surface, and in this case the protective film forming layer is usually laminated on the opposite surface to the surface on which the circuits are formed. By curing the singulated protective film forming layers at a predetermined timing, the chips can be formed with protective films having sufficient durability. The protective film forming layers may be preferably composed of an uncured curable adhesive.

### 4. Physical Properties of Sheets for Workpiece Processing

In the sheet for workpiece processing according to the present embodiment, its adhesive strength to a silicon wafer (the mirror surface of a mirror-finished silicon wafer, here and hereinafter) before heating and before active energy ray irradiation may be preferably 200 mN/25 mm or more, particularly preferably 800 mN/25 mm or more, and further preferably 2,000 mN/25 mm or more. When the adhesive strength is 200 mN/25 mm or more, the workpiece can be easily and well fixed onto the sheet for workpiece processing, and the unintended falling off (in particular, chip flying) of the workpiece or workpieces (in particular, the workpieces after singulation) can be readily prevented. The upper limit of the above adhesive strength is not particularly limited, but it may be, for example, preferably 30,000 mN/25 mm or less, particularly preferably 25,000 mN/25 mm or less, and further preferably 22,000 mN/25 mm or less.

Additionally or alternatively, in the sheet for workpiece processing according to the present embodiment, its adhesive strength to a silicon wafer before heating and after active energy ray irradiation may be preferably 1,500 mN/25 mm or less, particularly preferably 600 mN/25 mm or less, and further preferably 200 mN/25 mm or less. In the sheet for workpiece processing according to the present embodiment, since the pressure sensitive adhesive layer is composed of an active energy ray-curable pressure sensitive adhesive, the adhesive strength as described above can readily be achieved after active energy ray irradiation. When the above adhesive strength is 1,500 mN/25 mm or less, the workpiece or workpieces can be easily released from the sheet for workpiece processing. From another aspect, the adhesive strength may be preferably 10 mN/25 mm or more, particularly preferably 25 mN/25 mm or more, and further preferably 35 mN/25 mm or more. This makes it easier to prevent separation/falling off of the workpiece or workpieces at an unintended stage after active energy ray irradiation.

Additionally or alternatively, in the sheet for workpiece processing according to the present embodiment, its adhesive strength to a silicon wafer (the mirror surface of a mirror-finished silicon wafer, here and hereinafter) after heating and before active energy ray irradiation may be preferably 200 mN/25 mm or more, more preferably 800 mN/25 mm or more, particularly preferably 2,000 mN/25 mm or more, and further preferably 8,000 mN/25 mm or more. When the adhesive strength is 200 mN/25 mm or more, the workpiece can be easily and well fixed onto the sheet for workpiece processing, and the unintended falling off (in particular, chip flying) of the workpiece or workpieces (in particular, the workpieces after singulation) can be readily prevented. From another aspect, the above adhesive strength may be preferably 30,000 mN/25 mm or less, particularly preferably 25,000 mN/25 mm or less, and further preferably 15,000 mN/25 mm or less. When the adhesive strength is 30,000 mN/25 mm or less, the adhesive strength after heating and after active energy ray irradiation can be readily adjusted within a range, which will be described below.

Additionally or alternatively, in the sheet for workpiece processing according to the present embodiment, its adhesive strength to a silicon wafer after heating and after active energy ray irradiation may be preferably 1,500 mN/25 mm or less, more preferably 1,000 mN/25 mm or less, particularly preferably 600 mN/25 mm or less, and further preferably 200 mN/25 mm or less. In the sheet for workpiece processing according to the present embodiment, since the pressure sensitive adhesive layer is composed of an active energy ray-curable pressure sensitive adhesive that contains a hindered amine-based stabilizer, the adhesive strength after active energy ray irradiation can readily be reduced to the above range even after heating. When the above adhesive strength is 1,500 mN/25 mm or less, the workpiece or workpieces can be easily released from the sheet for workpiece processing. From another aspect, the adhesive strength may be preferably 10 mN/25 mm or more, particularly preferably 25 mN/25 mm or more, and further preferably 35 mN/25 mm or more. This makes it easier to prevent separation/falling off of the workpiece or workpieces at an unintended stage after active energy ray irradiation.

The details of a method of measuring the above adhesive strength are as described in the testing example, which will be described later.

### 5. Method of Manufacturing Sheet for Workpiece Processing

Methods of manufacturing the sheet for workpiece processing according to the present embodiment are not particularly limited, and it may be preferably manufactured by laminating the pressure sensitive adhesive layer on one side of the base material.

Lamination of the pressure sensitive adhesive layer on one side of the base material can be performed in any known method. For example, it may be preferred to form the pressure sensitive adhesive layer on a release sheet and then transfer the pressure sensitive adhesive layer to one side of the base material. In this case, the pressure sensitive adhesive layer can be formed through preparing a coating liquid that contains a pressure sensitive adhesive for constituting the pressure sensitive adhesive layer and, if desired, further contains a solvent or dispersion medium, coating a surface of the release sheet for which release treatment is performed (this surface may be referred to as a “release surface,” hereinafter) with the prepared coating liquid using a die coater, curtain coater, spray coater, slit coater, knife coater, applicator, etc. to form a coating film, and drying the coating film. Properties of the coating liquid are not particularly limited, provided that coating can be performed using the coating liquid. The components for forming the pressure sensitive adhesive layer may each be contained as a solute and/or a dispersant. In the obtained laminate, the release sheet may be removed as a process material and may also be used for protecting the pressure sensitive adhesive surface of the pressure sensitive adhesive layer until the sheet for workpiece processing is attached to an adherend.

When the coating liquid for forming the pressure sensitive adhesive layer contains a crosslinker, the conditions for the above drying (such as temperature and time) may be changed, or heating treatment may be separately provided, thereby to progressing the crosslinking reaction between the active energy ray-curable polymer (A) in the coating film and the crosslinker to form a crosslinked structure in the pressure sensitive adhesive layer with a desired existence density. To sufficiently progress the crosslinking reaction, aging may be performed such that, after the pressure sensitive adhesive layer is laminated on the base material using the above method or the like, the obtained sheet for workpiece processing is statically placed for several days, for example, under an environment of 23° C. and a relative humidity of 50%.

The pressure sensitive adhesive layer may be formed directly on the base material instead of transferring the pressure sensitive adhesive layer formed on the release sheet to one side of the base material as described above. In this case, the pressure sensitive adhesive layer may be formed through coating the one side of the base material with the previously-described coating liquid for forming the pressure sensitive adhesive layer to form a coating film and drying the coating film.

### 6. Method of Using Sheet for Workpiece Processing

The sheet for workpiece processing according to the present embodiment may be suitably used for processing a workpiece such as a semiconductor wafer. In this case, after the pressure sensitive adhesive surface of the sheet for workpiece processing according to the present embodiment is attached to the workpiece, processing of the workpiece can be performed on the sheet for workpiece processing. Depending on the processing, the sheet for workpiece processing according to the present embodiment can be used as a back grinding sheet, a dicing sheet, an expanding sheet, a pickup sheet, etc. Here, examples of workpieces include semiconductor members such as semiconductor wafers and semiconductor packages and glass members such as glass plates.

As described previously, the sheet for workpiece processing according to the present embodiment can satisfactorily reduce its adhesive strength to the workpiece or workpieces by irradiation with active energy rays even after heating treatment. This allows the workpiece or workpieces to be readily separated. Thus, the sheet for workpiece processing according to the present embodiment is particularly suitable for use in a workpiece processing method that includes a step of heating the sheet for workpiece processing in a state in which a workpiece or workpieces before or after processing are laminated on the pressure sensitive adhesive side.

For example, the sheet for workpiece processing according to the present embodiment can be suitably used in a method of manufacturing processed workpieces, comprising: a bonding step of bonding a workpiece to the surface of the pressure sensitive adhesive layer opposite to the base material; a heating step of subjecting the workpiece to a treatment that involves heating in a state in which the workpiece is laminated on the sheet for workpiece processing; and a dicing step of dicing, on the sheet for workpiece processing, the workpiece subjected to the treatment that involves heating, thereby obtaining processed workpieces that are singulated from the workpiece.

In the above-described method of manufacturing processed workpieces, the processed workpieces obtained by the dicing step can be appropriately separated from the sheet for workpiece processing. For example, the above manufacturing method may preferably include an active energy ray irradiation step and a pickup step. In the active energy ray irradiation step, the pressure sensitive adhesive layer of the sheet for workpiece processing to which the processed workpieces are attached is irradiated with active energy rays to cure the pressure sensitive adhesive layer. In the pickup step, the above processed workpieces are picked up from the sheet for workpiece processing which includes the cured pressure sensitive adhesive layer.

The above-described bonding step, dicing step, active energy ray irradiation step, and pickup step can be performed by respective known methods. The above-described heating step is also not particularly limited, and treatments such as vapor deposition, sputtering, and baking and/or heating tests to confirm reliability under high-temperature environments can be performed, for example, on a workpiece or workpieces before or after processing.

The heating conditions in the above heating step can be appropriately set depending on the purpose of heating. For example, the heating temperature may be 80° C. or higher in an embodiment, 100° C. or higher in another embodiment, or 110° C. or higher in still another embodiment. From another aspect, the temperature may be, for example, 300° C. or lower in an embodiment, 270° C. or lower in another embodiment, or 200° C. or lower in still another embodiment. The heating time may be, for example, 10 minutes or more in an embodiment, 30 minutes or more in another embodiment, or 120 minutes or more in still another embodiment. From another aspect, the time may be, for example, 25 hours or less in an embodiment, 10 hours or less in another embodiment, or 5 hours or less in still another embodiment. The device for heating can be used depending on the purpose of heating and, for example, an oven, a heating table, etc. can be used.

The embodiments heretofore explained are described to facilitate understanding of the present invention and are not described to limit the present invention. It is therefore intended that the elements disclosed in the above embodiments include all design changes and equivalents to fall within the technical scope of the present invention.

For example, another layer may be provided between the base material and the pressure sensitive adhesive layer or on the surface of the base material opposite to the pressure sensitive adhesive layer.

### EXAMPLES

Hereinafter, the present invention will be described further specifically with reference to examples, etc., but the scope of the present invention is not limited to these examples, etc.

### Example 1

### (1) Production of Base Material

A solution having a solid content concentration of 3% was obtained by mixing 100 mass parts (solid content equivalent, here and hereinafter) of a bisphenol A-type epoxy compound (available from DIC Corporation, product name “EPICLON H-360,” weight-average molecular weight: 25,000), 10.7 mass parts of a polyester compound (available from TOYOBO Co., Ltd., product name “Vylon GK680,” number average molecular weight: 6,000, glass transition temperature: 10° C.), and 28.5 mass parts of hexamethoxymethylmelamine (available from Nippon Cytec Industries Inc., product name “Cymel 303”) as a polyfunctional amino compound in a mixed solvent of toluene and methyl ethyl ketone with a mixing ratio (mass %) of 50:50. Furthermore, 1.45 mass parts of p-toluenesulfonic acid as an acidic catalyst was added to the solution and mixed to obtain a coating liquid for a composition for oligomer sealing layer.

One surface of a polyethylene terephthalate (PET) film (available from Toray Industries, Inc., product name “Lumirror T-60,” thickness: 75 μm) was uniformly coated with the coating liquid for the composition for oligomer sealing layer prepared in step (1) using a Mayer bar coating method. The coating film thus obtained was cured by heating in an oven to form a first oligomer sealing layer having a thickness of 135 nm.

Furthermore, the surface of the above PET film opposite to the first oligomer sealing layer was also coated with the coating liquid for the composition for oligomer sealing layer in the same manner as above, and the coating film thus obtained was cured to form a second oligomer sealing layer having a thickness of 135 nm.

Through the above steps, a base material having oligomer sealing layers formed on both surfaces of the PET film was obtained.

### (2) Preparation of Pressure Sensitive Adhesive Composition

A (meth)acrylic ester polymer was obtained by using a solution polymerization method to polymerize 60 mass parts of 2-ethylhexyl acrylate, 10 mass parts of N-acryloylmorpholine, and 30 mass parts of 2-hydroxyethyl acrylate. The weight-average molecular weight of the (meth)acrylic ester polymer was measured by the method described later and was found to be 500,000.

The obtained (meth)acrylic ester polymer was reacted with methacryloyloxyethyl isocyanate (MOI) in an amount equivalent to 90 mol % with respect to 2-hydroxyethyl acrylate constituting the (meth)acrylic ester polymer to obtain an acrylic-based polymer (active energy ray-curable polymer) in which an active energy ray-curable group was introduced into a side chain. The weight-average molecular weight (Mw) of the active energy ray-curable polymer was measured by the method described later and was found to be 500,000.

A coating liquid (solid content concentration: 30 mass parts) of a pressure sensitive adhesive composition was obtained by mixing 100 mass parts of the obtained active mass energy ray-curable polymer, 3.0 of parts 1-hydroxycyclohexyl phenyl ketone (available from IGM Resins, product name “Omnirad 184”) as photopolymerization initiator, 4.5 mass parts of an isocyanurate type trimer of 1,6-hexamethylene diisocyanate (available from Tosoh Corporation, product name “Coronate HX”) as a crosslinker, and 0.5 mass parts of tetrakis (2,2,6,6-tetramethyl-4-piperidyl)1,2,3,4-butanetetracarboxylate (available from ADEKA CORPORATION, product name “ADEKASTAB LA-52,” N-methyl type hindered amine-based stabilizer) as a hindered amine-based stabilizer in an solvent.

### (3) Formation of Pressure Sensitive Adhesive Layer

A release sheet (available from LINTEC Corporation, product name “SP-PET381031”) was prepared in which a silicone-based release agent layer was formed on a polyethylene terephthalate film having a thickness of 38 μm. The release surface of the release sheet was coated with the the pressure sensitive adhesive coating liquid of composition obtained in the above step (2), and the coating liquid was then dried by heating to form a laminate in which a pressure sensitive adhesive layer having a thickness of 10 μm was formed on the release sheet.

### (4) Production of Pressure Sensitive Adhesive Sheet

After corona treatment was applied to one surface of the base material obtained in the above step (1), the corona-treated surface and the surface on the pressure sensitive adhesive layer side of the laminate obtained in the above step (3) were bonded together, and the base material and the laminate were stored for 10 days under an environment of 23° C. and 50% in a light-shielded state. Thus, a sheet for workpiece processing was obtained.

### (5) Measurement of Weight-Average Molecular Weight (Mw) of (Meth)Acrylic Ester Copolymer

The above-described weight-average molecular weight (Mw) of the (meth)acrylic ester copolymer refers to a weight-average molecular weight that is measured as a polystyrene equivalent value under the following condition using gel permeation chromatography (GPC) (GPC measurement).

### «Measurement Condition»

GPC measurement device: HLC-8320 available from Tosoh Corporation
GPC columns (passing through in the following order): available from Tosoh Corporation
   TSK gel super H-H
   TSK gel super HM-H
   TSK gel super H2000
Solvent for measurement: tetrahydrofuran
Measurement temperature: 40° C.

### Examples 2 to 7

Sheets for workpiece processing were obtained in the same manner as in Example 1 except that the content of the crosslinker and the type and content of the hindered amine-based stabilizer were as listed in Table 1.

### Comparative Example 1

A sheet for workpiece processing was obtained in the same manner as in Example 1 except that the hindered amine-based stabilizer was not used.

### Comparative Example 2

A sheet for workpiece processing was obtained in the same manner as in Example 1 except that the hindered amine-based stabilizer was not used, and instead, octadecyl 3-(3,5-di-tert-butyl-4-hydroxyphenyl) propionate (available from ADEKA CORPORATION, product name “ADEKASTAB AO-50) as a hindered phenol-based stabilizer was used at a compounding amount of 0.5 mass parts.

### <Testing Example> (Measurement of Adhesive Strength)

The sheet for workpiece processing produced in each of Examples and Comparative Examples was cut into a strip with a width of 25 mm. The release sheet was removed from the obtained strip-shaped sheet for workpiece processing, and the exposed pressure sensitive adhesive surface of the pressure sensitive adhesive layer was attached to the mirror surface of a mirror-finished silicon wafer using a 2 kg rubber roller under an environment of a temperature of 23° C. and a relative humidity of 50% to form a sample for measurement.

For the obtained sample for measurement, 20 minutes after it was attached to the silicon wafer, the sheet for workpiece processing was peeled off from the silicon wafer at a peeling speed of 300 mm/min and a peeling angle of 180° under a condition of 23° C. using a universal tensile tester (available from ORIENTEC Co., LTD., product name “TENSILON UTM-4-100”), and the adhesive strength (mN/25 mm) to the silicon wafer was measured by a method of 180° peeling according to JIS Z0237:2009. The adhesive strength thus obtained was determined as the adhesive strength before heating and before UV irradiation (before heating-before UV). The results are listed in Table 1.

In addition, for the sample for measurement obtained in the same manner as above, 20 minutes after it was attached to the silicon wafer, an ultraviolet irradiation device (available from LINTEC Corporation, product name “RAD-2000 m/12”) was used to perform ultraviolet (UV) irradiation (light source: high-pressure mercury lamp, illuminance: 230 mW/cm², light amount: 190 mJ/cm²) under a condition of a temperature of 23° C. and a relative humidity of 50%. For the sample for measurement after the ultraviolet irradiation, measurement was performed by peeling off the sheet for workpiece processing from the silicon wafer in the same manner as above, and the adhesive strength (mN/25 mm) to the silicon wafer was measured. The adhesive strength thus obtained was determined as the adhesive strength before heating and after UV irradiation (before heating-after UV). The results are listed in Table 1.

In addition, the sample for measurement obtained in the same manner as above was heated in an oven at 170° C. for 1 hour in a state of being wrapped in aluminum foil. After heating, the sample for measurement was taken out of the oven and cooled by statically placing it at room temperature for 5 minutes, and then the adhesive strength (mN/25 mm) to the silicon wafer was measured in the same manner as above. The adhesive strength thus obtained was determined as the adhesive strength after heating and before UV irradiation (after heating-before UV). The results are listed in Table 1.

Furthermore, the sample for measurement obtained in the same manner as above was heated in an oven at 170° C. for 1 hour in a state of being wrapped in aluminum foil. After heating, the sample for measurement was taken out of the oven and cooled by statically placing it at room temperature for 5 minutes, and then the ultraviolet irradiation was performed under the same condition as above. For the sample for measurement the after ultraviolet irradiation, measurement was performed by peeling off the sheet for workpiece processing from the silicon wafer in the same manner as above, and the adhesive strength (mN/25 mm) to the silicon wafer was measured. The adhesive strength thus obtained was determined as the adhesive strength after heating and after UV irradiation (after heating-after UV). The results are listed in Table 1.

The details of the simplified names listed in Table 1 and additional information are as follows.
LA-52: tetrakis (2,2,6,6-tetramethyl-4-piperidyl) 1,2,3,4-butanetetracarboxylate (available from ADEKA CORPORATION, product name “ADEKASTAB LA-52,” N-methyl type hindered amine-based stabilizer)
LA-63P: mixed ester of 1,2,3,4-butanetetracarboxylic acid and 1,2,2,6,6-pentamethyl-4-piperidinol and 3,9-bis(2-hydroxy-1,1-dimethylethyl)-2,4,8,10-tetraoxaspiro[5.5]undecan (available from ADEKA CORPORATION, product name “ADEKASTAB LA-63P,” N-methyl type hindered amine-based stabilizer)
LA-57: tetrakis (1,2,2,6,6-pentamethyl-4-piperidyl)1,2,3,4-butanetetracarboxylate (available from ADEKA CORPORATION, product name “ADEKASTAB LA-57,” NH type hindered amine-based stabilizer)
AO-50: octadecyl 3-(3,5-di-tert-butyl-4-hydroxyphenyl) propionate (available from ADEKA CORPORATION, product name “ADEKASTAB AO-50)

TABLE 1

| | | Hindered amine- | | Hindered phenol- | | Adhesive strength (mN/25 mm) | | | |
|---|---|---|---|---|---|---|---|---|---|
| | Content of | based stabilizer | | based stabilizer | | Before | Before | After | After |
| | crosslinker | | Content | | Content | heating- | heating- | heating- | heating- |
| | (mass | | (mass | | (mass | before | after | before | after |
| | parts) | Type | parts) | Type | parts) | UV | UV | UV | UV |
| Example 1 | 4.5 | LA-52 | 0.5 | — | — | 4800 | 30 | 11200 | 590 |
| Example 2 | 4.5 | LA-63P | 0.5 | — | — | 4500 | 30 | 9200 | 160 |
| Example 3 | 1.5 | LA-63P | 1 | — | — | 7500 | 40 | 10500 | 260 |
| Example 4 | 0.9 | LA-63P | 1 | — | — | 9400 | 40 | 12000 | 270 |
| Example 5 | 0.9 | LA-63P | 5 | — | — | 9500 | 40 | 11000 | 110 |
| Example 6 | 0.9 | LA-63P | 10 | — | — | 9800 | 40 | 11000 | 100 |
| Example 7 | 4.5 | LA-57 | 0.5 | — | — | 4800 | 40 | 10650 | 1100 |
| Comparative | 4.5 | — | — | — | — | 4500 | 40 | 11400 | 5850 |
| Example 1 | | | | | | | | | |
| Comparative | 4.5 | — | — | AO-50 | 0.5 | 4400 | 30 | 10700 | 4600 |
| Example 2 | | | | | | | | | |

As found from Table 1, in the sheets for workpiece processing according to Examples, the adhesive strength was able to be reduced satisfactorily by ultraviolet irradiation when heating was not performed, and furthermore, even when heating was performed, the adhesive strength was able to be sufficiently reduced by ultraviolet irradiation. On the other hand, in the sheets for workpiece processing according to Comparative Example 1 in which no hindered amine-based stabilizer was used and Comparative Example 2 in which a hindered phenol-based compound was used instead of the hindered amine-based stabilizer, the adhesive strength was able to be reduced by ultraviolet irradiation as in Examples when heating was not performed, but when heating was performed, the adhesive strength was not able to be reduced satisfactorily even by ultraviolet irradiation.

### INDUSTRIAL APPLICABILITY

The sheet for workpiece processing of the present invention can be suitably used for processing of a workpiece such as a semiconductor wafer, and in particular, can be suitably used in a workpiece processing method that includes a step of heating the sheet for workpiece processing in a state in which a workpiece or workpieces before or after processing are laminated on the sheet for workpiece processing.

1. A sheet for workpiece processing, comprising:
a base material; and
a pressure sensitive adhesive layer laminated on one side of the base material,
the pressure sensitive adhesive layer being composed of an active energy ray-curable pressure sensitive adhesive that contains a hindered amine-based stabilizer.

2. The sheet for workpiece processing according to claim 1, wherein the hindered amine-based stabilizer is an N-alkyl type hindered amine-based stabilizer.

3. The sheet for workpiece processing according to claim 1, wherein the active energy ray-curable pressure sensitive adhesive is formed from a pressure sensitive adhesive composition that contains an acrylic-based polymer having a side chain to which an active energy ray-curable group is introduced and the hindered amine-based stabilizer.

4. The sheet for workpiece processing according to claim 1, wherein the sheet for workpiece processing is used in a workpiece processing method comprising a step of heating the sheet for workpiece processing in a state in which a workpiece or workpieces before or after processing are laminated on a side of the pressure sensitive adhesive layer opposite to the base material.

5. A method of manufacturing processed workpieces, comprising:
bonding a workpiece to a surface of the pressure sensitive adhesive layer opposite to the base material in the sheet for workpiece processing according to claim 1;
subjecting the workpiece to a treatment that involves heating in a state in which the workpiece is laminated on the sheet for workpiece processing; and
dicing, on the sheet for workpiece processing, the workpiece subjected to the treatment that involves heating, thereby obtaining processed workpieces that are singulated from the workpiece.
